(19) United States
(12) Patent Application Publication
(10) Pub. No.: US 2024/0290547 A1
(43) Pub. Date: Aug. 29, 2024

(54) THIN FILM CAPACITOR

(71) Applicant: TDK Corporation, Tokyo (JP)

(72) Inventors: Masahiro HIRAOKA, Tokyo (JP); Hitoshi SAITA, Tokyo (JP)

(21) Appl. No.: 18/588,629

(22) Filed: Feb. 27, 2024

Related U.S. Application Data
(60) Provisional application No. 63/448,790, filed on Feb. 28, 2023.

(51) Int. Cl. H01G 4/33; H01G 4/012; H01G 4/228; H01L 23/00; H01L 23/498

(52) U.S. Cl. CPC H01G 4/33; H01G 4/012; H01G 4/228; H01L 23/49822; H01L 24/48; H01L 28/55; H01L 28/60; H01L 2224/48465; H01L 2924/19041

(57) ABSTRACT

Disclosed herein is a thin film capacitor that includes a capacitor part having a lower electrode, an inner electrode, and a dielectric layer positioned between the lower electrode and the inner electrode, an insulating layer covering the capacitor part, a terminal electrode provided on the insulating layer, and a plurality of via holes penetrating the insulating layer so that the terminal electrode and the inner electrode of the capacitor part are connected to each other via the plurality of via holes. The terminal electrode includes a via region on which the plurality of via holes are arranged and having a ring-shaped, and a bonding region surrounded by the via region and having flat-shaped.

### CROSS-REFERENCE TO RELATED APPLICATION

This application claims the benefit of Provisional Patent Application No. 63/448,790, filed on Feb. 28, 2023, the entire disclosure of which is incorporated by reference herein.

### BACKGROUND OF THE ART

### Field of the Art

The present disclosure relates to a thin film capacitor.

### Description of Related Art

Along with recent miniaturization of electronic devices, electronic components such as capacitors used for electronic devices are also required to be reduced in size and height. As a capacitor meeting this requirement, a thin film capacitor is now much in demand.

Meanwhile, for noise decoupling during high-speed operation of an IC, it is necessary to dispose a capacitor as close to the IC as possible. For example, a mounting configuration can be employed, in which a thin film capacitor is disposed on a substrate surface close to the IC, and the thin capacitor and an electrode on the substrate are connected using a bonding wire.

When a thin film capacitor and an electrode are connected using a bonding wire, damage at wire bonding needs to be avoided. That is, when a thin film capacitor is connected to a circuit board or other components using a bonding wire, an impact of ultrasonic waves at the time of forming a wire ball is applied to the thin film capacitor. The thin film capacitor has reduced height and thickness and is thus vulnerable to a mechanical impact, which may cause risks such as cracks and peeling. When the intensity of the ultrasonic wave is reduced to protect the thin film capacitor, adhesion strength of the bonding wire is lowered.

### SUMMARY

An object of the present disclosure is to provide a thin film capacitor capable of reducing damage on the internal structure thereof at wire bonding and maintaining high adhesion strength with respect to a bonding wire.

A thin film capacitor according to one embodiment of the present disclosure includes a capacitor part having a lower electrode, an inner electrode, and a dielectric layer positioned between the lower electrode and the inner electrode, an insulating layer covering the capacitor part, a terminal electrode provided on the insulating layer, and a plurality of via holes penetrating the insulating layer so that the terminal electrode and the inner electrode of the capacitor part are connected to each other via the plurality of via holes. The terminal electrode includes a via region on which the plurality of via holes are arranged and having a ring-shaped, and a bonding region surrounded by the via region and having flat-shaped.

### BRIEF DESCRIPTION OF THE DRAWINGS

The above features and advantages of the present disclosure will be more apparent from the following description of certain preferred embodiments taken in conjunction with the accompanying drawings, in which:

FIG. 1A is a schematic plan view for explaining the structure of a thin film capacitor 1 according to a first embodiment of the present disclosure;

FIG. 1B is a cross-sectional view taken along the line A-A in FIG. 1A;

FIG. 1C is a schematic cross-sectional view for explaining the structure of the thin film capacitor 1 according to a modification;

FIG. 2 is a plan view of a terminal electrode 30;

FIG. 3 is a schematic view illustrating a state where wire bonding is made to the thin film capacitor 1;

FIG. 4A is a schematic view illustrating an example in which the thin film capacitor 1 is mounted on a substrate 50;

FIG. 4B is a schematic view illustrating an example in which the thin film capacitor 1 is incorporated in a multilayer substrate 60;

FIG. 5 is a schematic cross-sectional view for explaining the structure of a thin film capacitor 2 according to a second embodiment of the present disclosure;

FIG. 6 is a schematic cross-sectional view for explaining the structure of a thin film capacitor 3 according to a third embodiment of the present disclosure;

FIG. 7 is a schematic cross-sectional view for explaining the structure of a thin film capacitor 4 according to a fourth embodiment of the present disclosure;

FIG. 8 is a schematic cross-sectional view for explaining the structure of a thin film capacitor 5 according to a fifth embodiment of the present disclosure;

FIG. 9A is a schematic plan view for explaining the structure of a thin film capacitor 6 according to a sixth embodiment of the present disclosure;

FIG. 9B is a schematic cross-sectional view taken along the line A-A in FIG. 9A;

FIG. 10A is a schematic plan view for explaining the structure of a thin film capacitor 7 according to a seventh embodiment of the present disclosure; and

FIG. 10B is a schematic cross-sectional view taken along the line A-A in FIG. 10A.

### DETAILED DESCRIPTION OF THE EMBODIMENTS

Some embodiments of the present disclosure will be explained below in detail with reference to the accompanying drawings.

### First Embodiment

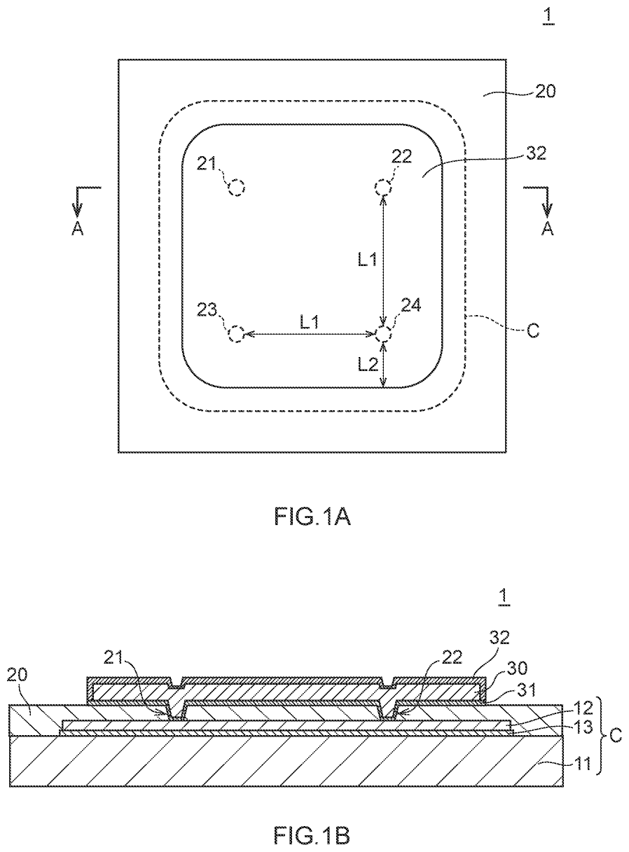

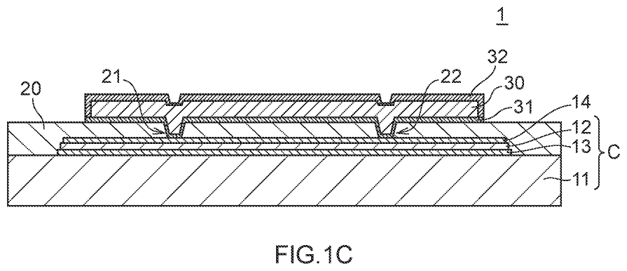

FIG. 1A is a schematic plan view for explaining the structure of a thin film capacitor 1 according to a first embodiment of the present disclosure. FIG. 1B is a cross-sectional view taken along the line A-A in FIG. 1A.

The thin film capacitor 1 according to the first embodiment includes a capacitor part C, an insulating layer 20 covering the capacitor part C, and a terminal electrode 30 provided on the insulating layer 20. The capacitor part C is constituted by a lower electrode 11, an inner electrode 12, and a dielectric layer 13 positioned between the lower and inner electrodes 11 and 12. The lower and inner electrodes 11 and 12 are made of a metal material such as Ni. The lower electrode 11 has a planar size of, for example, 500 μm×500 μm. As illustrated in FIG. 1C, which is a modification of FIG. 1B, the upper surface of the inner electrode 12 made of a metal material such as Ni may be covered with a metal layer 14 made of metal material such as Cu. The inner electrode 12 and dielectric layer 13 are not provided on the entire upper surface of the lower electrode 11 but provided on a part excluding the outer peripheral region of the upper surface of the lower electrode 11. The inner electrode 12 and dielectric layer 13 have a planar size of, for example, 400 μm×400 μm. The planar shape of the inner electrode 12 and dielectric layer 13 may be a rectangle having rounded corners.

The dielectric layer 13 is made of a perovskite dielectric material. Examples of the perovskite dielectric material include a ferroelectric material or a paraelectric material having a perovskite structure, such as BaTiO₃ (barium titanate), (Ba₁₋ₓSrₓ)TiO₃ (barium strontium titanate), (Ba₁₋ₓCaₓ)TiO₃, PbTiO₃, Pb(ZrₓTi₁₋ₓ)O₃, (Sr₁₋ₓCaₓ), (Ti_{1-Y}Zr_{Y}), Ba(Mg_{1/3}Ta_{2/3}), a composite perovskite relaxer type ferroelectric material represented by Pb(Mg_{1/3}Nb_{2/3})O₃, and the like, a bismuth layer compound represented by Bi₄Ti₃O₁₂, a tungsten bronze type ferroelectric material represented by (Sr₁₋ₓBaₓ) Nb₂O₆ and PbNb₂O₆. Here, in the above-described perovskite structure, perovskite relaxer type ferroelectric material, bismuth layer compound, and tungsten bronze type ferroelectric material, the ratio of A site and B site is usually an integer ratio but may be purposefully shifted from the integer ratio in order to improve characteristics. In order to control the characteristics of the dielectric layer 13, the dielectric layer 13 may appropriately contain an additive substance as a subcomponent. The relative permittivity (εᵣ) is 10 or more, for example. The larger the relative permittivity of the dielectric layer 13, the better, and there is not particular restriction on the upper limit value thereof. Further, the larger the dielectric withstand voltage of the dielectric layer 13, the better, and there is not particular restriction on the upper limit value thereof. The thickness of the dielectric layer 13 is about 10 nm to about 6000 nm, for example.

The insulating layer 20 is made of a polyimide-based, epoxy-based, phenol-based, polyamide-based, or fluorine-based resin material, for example. The insulating layer 20 covers not only the upper surface of the inner electrode 12, but also the side surface of the inner electrode 12, the side surface of the dielectric layer 13, and a part of the upper surface of the lower electrode 11 that is not covered with the inner electrode 12 and dielectric layer 13. This prevents the inner electrode 12 and dielectric layer 13 from being exposed and makes the insulating layer 20 unlikely to peel off. The insulating layer 20 may have a Young's modulus of 0.1 GPa or more and 2.0 GPa or less. When the Young's modulus of the insulating layer 20 falls within the above range, an impact to be applied to the capacitor part C at wire bonding is relaxed.

The terminal electrode 30 is made of a metal material such as Cu. The lower surface of the terminal electrode 30 may be covered with an underlying metal layer 31. The upper and side surfaces of the terminal electrode 30 may be covered with a surface treatment layer 32. The underlying metal layer 31 may be a seed layer used to form the terminal electrode 30 by electrolytic plating. The surface treatment layer 32 is made of a metal material such as Ni, NiAu, NiPdAu, or SnAg. Providing the surface treatment layer 32 enhances adhesion to the bonding wire. Further, covering the side surface of the terminal electrode 30 with the surface treatment layer 32 equalizes stress by the surface treatment layer 32, making the terminal electrode 30 unlikely to peel off. The underlying metal layer 31 and surface treatment layer 32 may be regarded as a part of the terminal electrode 30, and thus the underlying metal layer 31 and surface treatment layer 32 are sometimes referred to as the terminal electrode 30 in the present specification. The planar shape of the terminal electrode 30 may be a rectangle having rounded corners. The terminal electrode 30 has a planar size of 350 μm×350 μm, for example. The curvature radius of the corner is 10 m or more and 100 m or less, for example. Rounding the corners of the terminal electrode 30 reduces a risk that the terminal electrode 30 is peeled starting from the corners to enhance bondability. However, excessively large curvature radius reduces the area of the terminal electrode.

The insulating layer 20 has a plurality of via holes 21 to 24 formed therein. The via holes 21 to 24 penetrate the insulating layer 20 and are each filled with a metal material constituting the terminal electrode 30. When the underlying metal layer 31 is provided on the lower surface of the terminal electrode 30, the underlying metal layer 31 is also filled in the via holes 21 to 24. As a result, the inner electrode 12 of the capacitor part C is connected to the terminal electrode 30 through the plurality of via holes 21 to 24. The via holes 21 to 24 may be filled with a metal material constituting the inner electrode 12. The via holes 21 to 24 each have a substantially circular planar shape and may have a diameter ϕ of 10 μm or more and 100 μm or less. For example, the diameter ϕ can be set to 20 μm. The via holes 21 to 24 may have a tapered cross section. The distance between each of the via holes 21 to 24 and the edge of the insulating layer 20 is 150 μm, for example. A minimum distance L1 between the via holes 21 to 24 is larger than a minimum distance L2 between each of the via holes 21 to 24 and the outer peripheral edge of the terminal electrode 30. The distance L1 may be double or more of the distance L2. For example, the distances L1 and L2 are 200 μm and 75 μm, respectively.

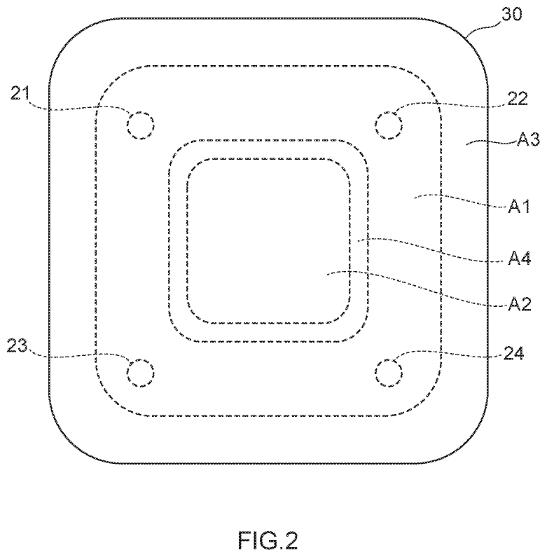

FIG. 2 is a plan view of the terminal electrode 30.

As illustrated in FIG. 2, a ring-shaped via region A1 and a bonding region A2 are defined on the upper surface of the terminal electrode 30. The bonding region A2 is positioned at the center of the upper surface of the terminal electrode 30 so as to be surrounded by the via region A1. The via region A1 is a region where the four via holes 21 to 24 are arranged. More via holes may be arranged in the via region A1. The boding region A2 is a region for connecting the bonding wire and has no via hole. The via region A1 has, in its surface, recesses at portions overlapping the via holes 21 to 24. On the other hand, the surface of the bonding region A2 is flat since no via hole is formed at a position overlapping the bonding region A2. A region A3 positioned outside the via region A1 and a region A4 positioned between the via region A1 and the bonding region A2 have no via holes and are not connected with the bonding wire. The width of the region A3 is 50 μm, for example. In this case, the via holes 21 to 24 are positioned apart from the outer peripheral edge of the terminal electrode 30 by 50 μm or more. The width of the region A4 is 50 μm, for example. In this case, the via holes 21 to 24 are positioned apart from the bonding region A2 by 50 μm or more.

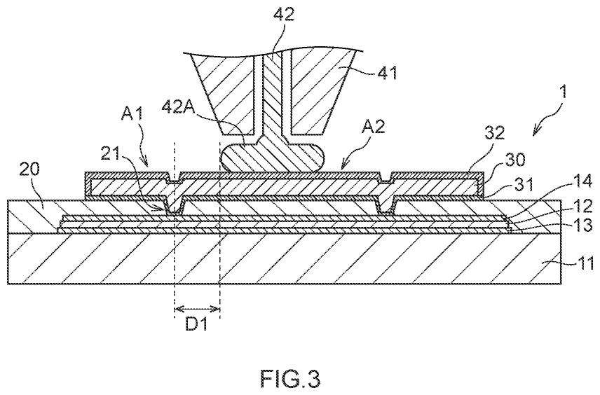

FIG. 3 is a schematic view illustrating a state where wire bonding is made to the thin film capacitor 1 according to the present embodiment.

As illustrated in FIG. 3, when wire bonding is made to the thin film capacitor 1, a bonding wire 42 made of Au or the like is bonded to the bonding region A2 of the terminal electrode 30 using a capillary 41. As described above, no via hole is formed at a position overlapping the bonding region A2, so that the bonding region A2 has a flat surface. This enhances bonding strength and reduces damage to the capacitor part C through the via holes 21 to 24. The diameter of the bonding region A2 is preferably larger than the diameter of the capillary 41 at its tip end. For example, when the diameter of the capillary 41 at its tip end is 100 μm, the diameter of the bonding region A2 can be set to 150 μm. When a ball bond part 42A of the bonding wire 42 contacting the terminal electrode 30 is located within the bonding region A2, a distance D1 between the ball bond part 42A and each of the via holes 21 to 24 in a plan view can be made equal to or more than the width (for example, 50 μm) of the region A4.

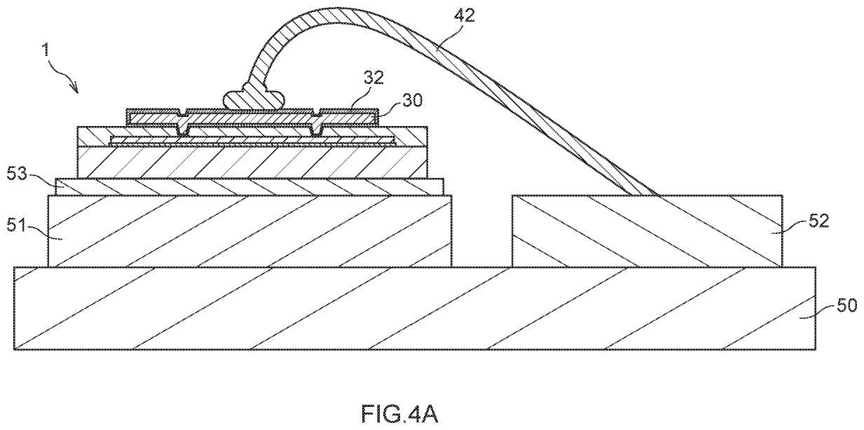

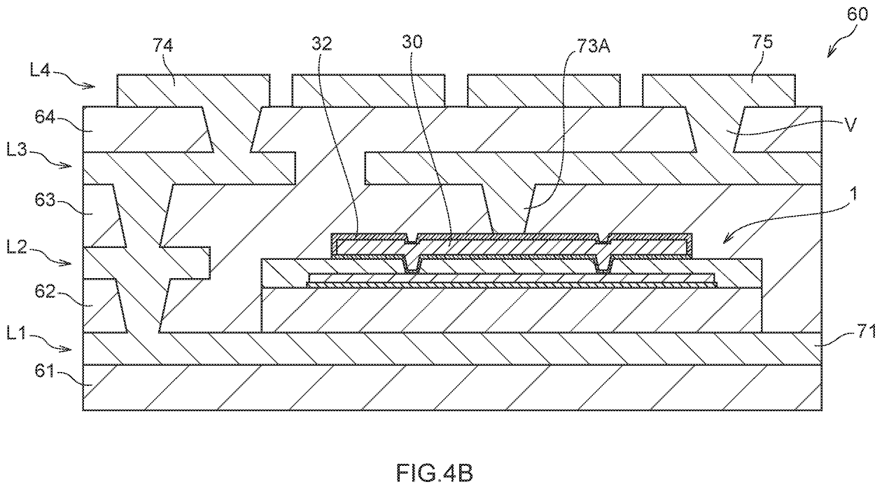

FIG. 4A is a schematic view illustrating an example in which the thin film capacitor 1 according to the present embodiment is mounted on a substrate 50.

There are provided electrode patterns 51 and 52 on the surface of the substrate 50 illustrated in FIG. 4A. The thin film capacitor 1 is mounted on the surface of the electrode pattern 51 through a conductive adhesive member 53 such as a solder. Thus, the lower electrode 11 of the capacitor part C included in the thin film capacitor 1 is connected to the electrode pattern 51. The terminal electrode 30 of the thin film capacitor 1 is connected to the electrode pattern 52 through the bonding wire 42. Thus, the inner electrode 12 of the capacitor part C included in the thin film capacitor 1 is connected to the electrode pattern 52. As a result, capacitance is provided between the electrode patterns 51 and 52 by the capacitor part C. The thin film capacitor 1 according to the present embodiment can thus be mounted on a substrate surface.

FIG. 4B is a schematic view illustrating an example in which the thin film capacitor 1 according to the present embodiment is incorporated in a multilayer substrate 60.

The multilayer substrate 60 illustrated in FIG. 4B has a structure in which a plurality of insulating layers 61 to 64 and a plurality of conductor layers L1 to L4 are alternately stacked. Conductor patterns positioned in different conductor layers are connected to one another through via conductors V. In the example illustrated in FIG. 4B, the thin film capacitor 1 is embedded in the insulating layers 62 and 63 such that the lower electrode 11 contacts the conductor pattern 71 positioned in the conductor layer L1 and that the terminal electrode 30 contacts a via conductor 73A. As a result, capacitance is provided between electrode patterns 74 and 75 positioned in the conductor layer L4 by the capacitor part C. The thin film capacitor 1 according to the present embodiment can thus be incorporated in a multilayer substrate.

### Second Embodiment

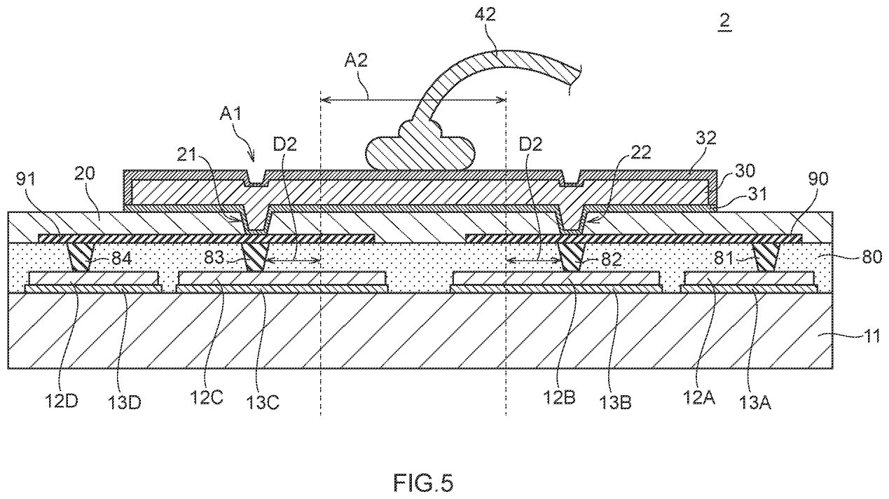

FIG. 5 is a schematic cross-sectional view for explaining the structure of a thin film capacitor 2 according to a second embodiment of the present disclosure.

The thin film capacitor 2 according to the second embodiment has additionally another insulating layer 80 provided between the capacitor part C and the insulating layer 20 and rewiring layers 90 and 91 provided on the surface of the insulating layer 80. Further, the inner electrode 12 is divided into four inner electrodes 12A to 12D, and the dielectric layer 13 is divided into four dielectric layers 13A to 13D. The dielectric layers 13A to 13D are respectively positioned between the lower electrode 11 and the inner electrodes 12A to 12D. Other basic configurations are the same as those of the thin film capacitor 1 according to the first embodiment, so the same reference numerals are given to the same elements, and overlapping description will be omitted.

Like the insulating layer 20, the insulating layer 80 is made of a polyimide-based, epoxy-based, phenol-based, polyamide-based, or fluorine-based resin material, for example. The resin material constituting the insulating layer 20 and that constituting the insulating layer 80 may be the same as or different from each other. The rewiring layers 90 and 91 are provided on the upper surface of the insulating layer 80 so as to be sandwiched between the insulating layers 80 and 20. The rewiring layer 90 is connected to the terminal electrode 30 through the via hole 22, and the rewiring layer 91 is connected to the terminal electrode 30 through the via hole 21. The insulating layer 80 has a plurality of via holes 81 to 84. The via holes 81 to 84 may be filled with the same metal material as that constituting the rewiring layers 90 and 91.

The rewiring layer 90 is further connected to the inner electrode 12A through the via hole 81 and to the inner electrode 12B through the via hole 82. The rewiring layer 91 is further connected to the inner electrode 12C through the via hole 83 and to the inner electrode 12D through the via hole 84. As a result, the four divided capacitor parts C are connected to one another through the rewiring layers 90 and 91.

In the example illustrated in FIG. 5, the via holes 82 and 83 are disposed at positions overlapping the via region A1 in a plan view. For example, the via hole 21 and via hole 83 are disposed at a position overlaying each other in a plan view, and the via hole 22 and via hole 82 are disposed at a position overlaying each other in a plan view. This ensures the distance D2 between the via holes 82, 83 and the bonding region A2 in the planar direction, reducing damage to the capacitor part C through the via holes 82 and 83. In addition, in the example illustrated in FIG. 5, the dielectric layer 13 is removed at a position overlapping the bonding region A2, thereby also reducing damage to the capacitor part C at a portion immediately below the bonding wire 42.

### Third Embodiment

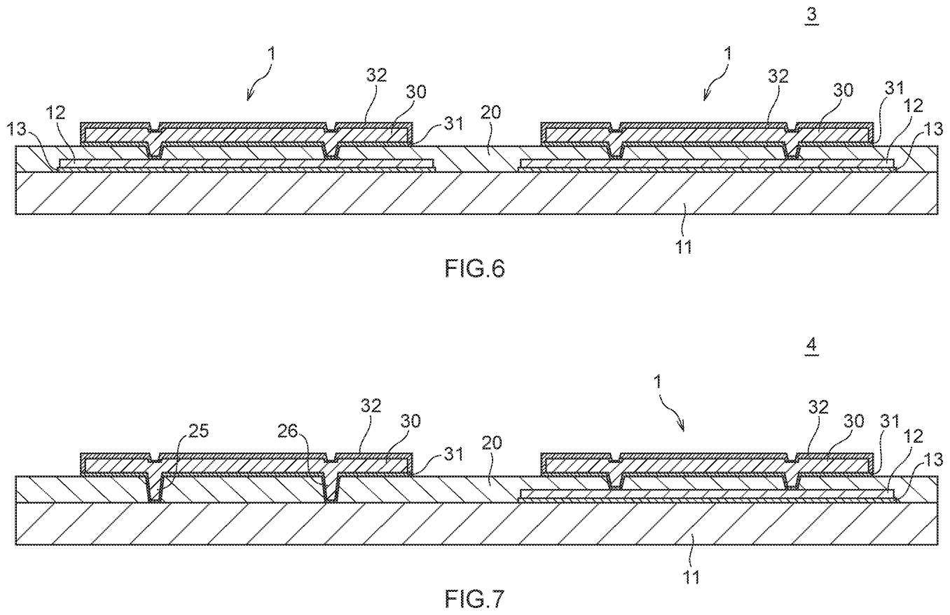

FIG. 6 is a schematic cross-sectional view for explaining the structure of a thin film capacitor 3 according to a third embodiment of the present disclosure.

The thin film capacitor 3 according to the third embodiment includes two thin film capacitors 1 having the common lower electrode 11. That is, two dielectric layers 13 and two inner electrodes 12 are provided on the surface of the lower electrode 11 so as to be embedded in the insulating layer 20. Two terminal electrodes 30 are provided on the surface of the insulating layer 20 and each connected to its corresponding inner electrode 12 through a plurality of via holes. The planar size of the dielectric layer 13 included in each of the two thin film capacitors 1 may be the same as or different from each other. When the thin film capacitor 3 is thus constituted by the plurality of thin film capacitors 1 having the common lower electrode 11, there can be provided a plurality of capacitors having various capacitances.

### Fourth Embodiment

FIG. 7 is a schematic cross-sectional view for explaining the structure of a thin film capacitor 4 according to a fourth embodiment of the present disclosure.

The thin film capacitor 4 according to the fourth embodiment differs from the thin film capacitor 3 according to the third embodiment in that one of the two terminal electrodes 30 is connected to the lower electrode 11 through a via hole. Other basic configurations are the same as those of the thin film capacitor 3 according to the third embodiment, so the same reference numerals are given to the same elements, and overlapping description will be omitted. With this configuration, the capacitor part C is connected between one terminal electrode 30 and the other terminal electrode 30.

### Fifth Embodiment

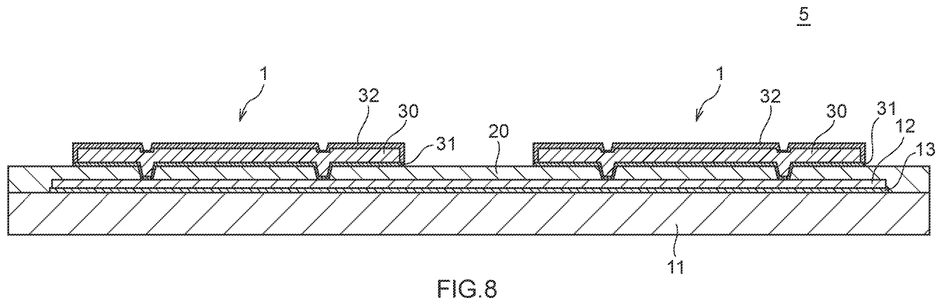

FIG. 8 is a schematic cross-sectional view for explaining the structure of a thin film capacitor 5 according to a fifth embodiment of the present disclosure.

The thin film capacitor 5 according to the fifth embodiment differs from the thin film capacitor 3 according to the third embodiment in that the inner electrode 12 and dielectric layer 13 are shared by the plurality of terminal electrodes 30. Other basic configurations are the same as those of the thin film capacitor 3 according to the third embodiment, so the same reference numerals are given to the same elements, and overlapping description will be omitted. As described above, the plurality of terminal electrodes 30 may be provided for one inner electrode 12.

### Sixth Embodiment

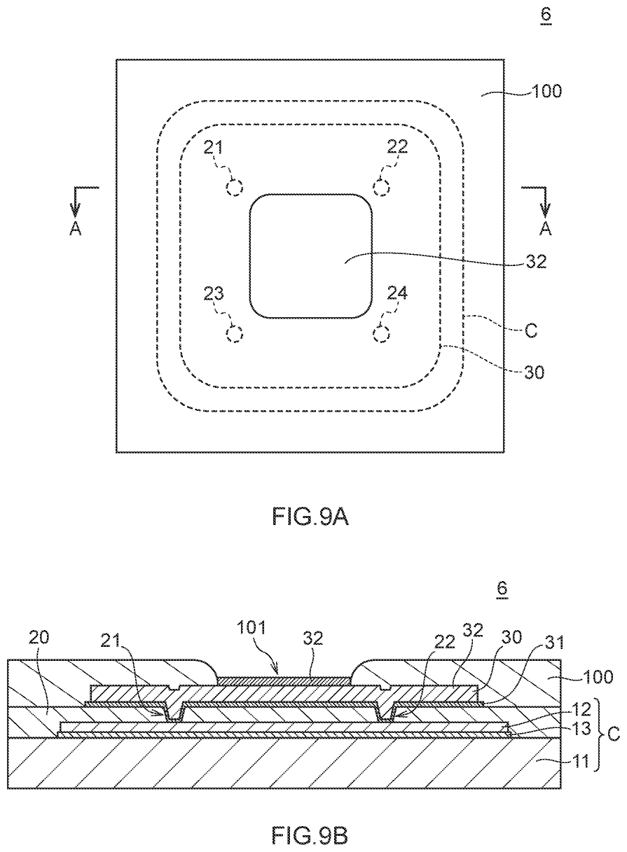

FIG. 9A is a schematic plan view for explaining the structure of a thin film capacitor 6 according to a sixth embodiment of the present disclosure. FIG. 9B is a schematic cross-sectional view taken along the line A-A in FIG. 9A.

The thin film capacitor 6 according to the sixth embodiment differs from the thin film capacitor 1 according to the first embodiment in that the surfaces of the insulating layer 20 and terminal electrode 30 are partially covered with a solder resist 100. Other basic configurations are the same as those of the thin film capacitor 1 according to the first embodiment, so the same reference numerals are given to the same elements, and overlapping description will be omitted.

The solder resist 100 covers the surface of the insulating layer 20 exposed from the terminal electrode 30 and covers the via region A1 of the terminal electrode 30. The bonding region A2 of the terminal electrode 30 is not covered with the solder resist 100 but exposed through an opening 101 of the solder resist 100. The surface of the terminal electrode 30 exposed through the opening 101 of the solder resist 100 is covered with the surface treatment layer 32. The surface treatment layer 32 is not provided on a part of the surface of the terminal electrode 30 that is covered with the solder resist 100. This reduces the area of the surface on which the surface treatment layer 32 is to be formed, allowing a reduction in material cost.

### Seventh Embodiment

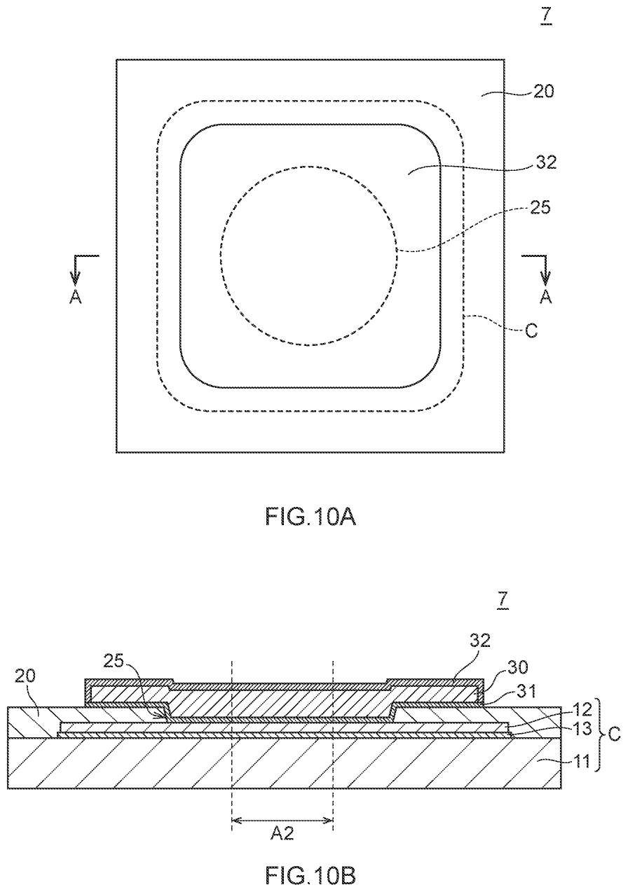

FIG. 10A is a schematic plan view for explaining the structure of a thin film capacitor 7 according to a seventh embodiment of the present disclosure. FIG. 10B is a schematic cross-sectional view taken along the line A-A in FIG. 10A.

The thin film capacitor 7 according to the seventh embodiment differs from the thin film capacitor 1 according to the first embodiment in that the inner electrode 12 and the terminal electrode 30 are connected through a large diameter via hole 25 overlapping the entire bonding region A2. Other basic configurations are the same as those of the thin film capacitor 1 according to the first embodiment, so the same reference numerals are given to the same elements, and overlapping description will be omitted.

The via hole 25 is positioned at the center of the terminal electrode 30 in a plan view so as to overlap the entire bonding region A2. The opening area of the via hole 25 is larger than the area of the bonding region A2. Using the large diameter via hole 25 can make the surface of the bonding region A2 overlapping the via hole 25 flat, allowing achievement of high bonding strength. In addition, this prevents impact to be applied to the capacitor part C during the wire bonding process from concentrating on one point.

While the preferred embodiment of the present disclosure has been described, the present disclosure is not limited to the above embodiment, and various modifications may be made within the scope of the present disclosure, and all such modifications are included in the present disclosure.

What is claimed is:

1. A thin film capacitor comprising:
a capacitor part having a lower electrode, an inner electrode, and a dielectric layer positioned between the lower electrode and the inner electrode;
an insulating layer covering the capacitor part;
a terminal electrode provided on the insulating layer; and
a plurality of via holes penetrating the insulating layer so that the terminal electrode and the inner electrode of the capacitor part are connected to each other via the plurality of via holes,
wherein the terminal electrode includes:
a via region on which the plurality of via holes are arranged and having a ring-shaped; and
a bonding region surrounded by the via region and having flat-shaped.

2. The thin film capacitor as claimed in claim 1, wherein the plurality of via holes are apart from an outer peripheral edge of the terminal electrode by 50 μm or more.

3. The thin film capacitor as claimed in claim 1, wherein the plurality of via holes are apart from the bonding region by 50 μm or more.

4. The thin film capacitor as claimed in claim 1, wherein each of the plurality of via holes has a substantially circular planar shape and has a diameter of 10 μm or more and 100 μm or less.

5. The thin film capacitor as claimed in claim 1, wherein each of the plurality of via holes has a tapered cross-sectional shape.

6. The thin film capacitor as claimed in claim 1, wherein each of the plurality of via holes is filled with a metal material.

7. The thin film capacitor as claimed in claim 6, wherein the metal material is made of Ti, Ni, Cr, Cu, or a laminated film thereof.

8. The thin film capacitor as claimed in claim 6, wherein the metal material includes a material constituting the terminal electrode.

9. The thin film capacitor as claimed in claim 1, wherein the terminal electrode is covered with a surface treatment layer.

10. The thin film capacitor as claimed in claim 9, wherein the surface treatment layer is made of Ni, NiAu, NiPdAu, or SnAg.

11. The thin film capacitor as claimed in claim 9, wherein the surface treatment layer covers top and side surfaces of the terminal electrode.

12. The thin film capacitor as claimed in claim 1, wherein a Young's modulus of the insulating layer is 0.1 GPa or more and 2.0 GPa or less.

13. The thin film capacitor as claimed in claim 1, wherein the insulating layer covers a surface of the internal electrode and a portion of a surface of the lower electrode that is not covered with the internal electrode.

14. The thin film capacitor as claimed in claim 1, wherein corners of the terminal electrode are rounded.

15. The thin film capacitor as claimed in claim 1, wherein a minimum distance between the via holes is greater than a minimum distance between any of the via holes and an outer peripheral edge of the terminal electrode.

16. The thin film capacitor as claimed in claim 1, further comprising a solder resist covering the via region of the terminal electrode without covering the bonding region of the terminal electrode.

17. The thin film capacitor as claimed in claim 16, wherein the bonding region of the terminal electrode is covered with a surface treatment layer such that the surface treatment layer is not covered with the solder resist.

18. A thin film capacitor comprising:
a capacitor part having a lower electrode, an inner electrode, and a dielectric layer positioned between the lower electrode and the inner electrode;
an insulating layer covering the capacitor part;
a terminal electrode provided on the insulating layer; and
a plurality of via holes penetrating the insulating layer so that the terminal electrode and the inner electrode of the capacitor part are connected to each other via the plurality of via holes,
wherein a first minimum distance between the via holes is greater than a second minimum distance between any of the via holes and an outer peripheral edge of the terminal electrode.

19. The thin film capacitor as claimed in claim 18, wherein the first minimum distance is greater than or equal to twice the second minimum distance.

20. An apparatus comprising:
a substrate having a first electrode and a second electrode;
a thin film capacitor mounted on the first electrode of the substrate; and
a bonding wire that connects the thin film capacitor and the second electrode of the substrate,
wherein the thin film capacitor comprises:
a capacitor part having a lower electrode, an inner electrode, and a dielectric layer positioned between the lower electrode and the inner electrode;
an insulating layer covering the capacitor part;
a terminal electrode provided on the insulating layer; and
a plurality of via holes penetrating the insulating layer so that the terminal electrode and the inner electrode of the capacitor part are connected to each other via the plurality of via holes,
wherein the thin film capacitor is mounted on the first electrode of the substrate such that the lower electrode is connected to the first electrode of the substrate,
wherein the terminal electrode includes:
a via region on which the plurality of via holes are arranged and having a ring-shaped; and
a bonding region surrounded by the via region, and
wherein the bonding wire is bonded to the bonding region of the terminal electrode without bonded to the via region of the terminal electrode.
